(19) United States
(12) Patent Application Publication
(10) Pub. No.: US 2024/0242994 A1
(43) Pub. Date: Jul. 18, 2024

(54) CONVEYANCE APPARATUS, CONVEYANCE METHOD, LITHOGRAPHY APPARATUS, AND ARTICLE MANUFACTURING METHOD

(71) Applicant: CANON KABUSHIKI KAISHA, Tokyo (JP)

(72) Inventor: OSAMU YASUNOBE, Tochigi (JP)

(21) Appl. No.: 18/402,094

(22) Filed: Jan. 2, 2024

(30) Foreign Application Priority Data
Jan. 17, 2023 (JP) 2023-005314

(51) Int. Cl. H01L 21/677; G03F 7/00; H01L 21/67

(52) U.S. Cl. CPC H01L 21/67742; G03F 7/70391; H01L 21/67225

(57) ABSTRACT

A conveyance apparatus for conveying a substrate is provided. The apparatus includes a movable base, a holding unit attached to the base and configured to hold the substrate and be movable with respect to the base, a cover plate attached to the base, and a driver configured to drive the base and the holding unit. The driver is configured to, in a state in which the cover plate covers a surface of the substrate held by a substrate chuck, drive the holding unit between a first space on a side of a substrate chuck where interference with the substrate chuck does not occur and a second space between a chuck surface of the substrate chuck and the substrate raised from the chuck surface.

### BACKGROUND OF THE INVENTION

### Field of the Invention

The present invention relates to a conveyance apparatus, a conveyance method, a lithography apparatus, and an article manufacturing method.

### Description of the Related Art

There is a demand for microfabrication of semiconductor devices, Micro Electro Mechanical Systems (MEMS), and the like, and an imprint technique of molding an imprint material on a substrate using a mold has received a great deal of attention. According to an imprint apparatus employing the imprint technique, it is possible to form a fine structure on an order of several nanometers on a substrate. The imprint apparatus is also used not only to manufacture a semiconductor device or the like but also to manufacture a replica mold from a master mold.

In the imprint technique, an imprint material with high volatility is often used. Hence, it is demanded to suppress evaporation of the imprint material. In addition, if an imprint process is executed while keeping a foreign substance (particle) adhered to a substrate, a pattern with a defect may be formed on the substrate, or the substrate or mold may be broken. It is therefore important to prevent a foreign substance from adhering to a substrate.

Japanese Patent Laid-Open No. 2003-142552 discloses a method of sealing the upper portion of a substrate by covering it with a box, thereby reducing adhesion of a foreign substance to the substrate.

A molding apparatus such as an imprint apparatus can include a plurality of substrate holding units for executing various kinds of substrate processes. Even in conveyance of a substrate to one of the plurality of substrate holding units, evaporation of a chemical liquid (including an imprint material) on the substrate progresses, and possibility of foreign substance adhesion becomes high. Hence, it is necessary to suppress these. The technique disclosed in Japanese Patent Laid-Open No. 2003-142552 may be insufficient as solutions to the problems of the chemical liquid volatilization and foreign substance adhesion when conveying a substrate from one substrate holding unit to another substrate holding unit.

### SUMMARY OF THE INVENTION

The present invention provides a technique advantageous in reducing evaporation of a chemical liquid applied to a substrate and foreign substance adhesion to the substrate.

The present invention in its one aspect provides a conveyance apparatus for conveying a substrate, including a movable base, a holding unit attached to the base and configured to hold the substrate and be movable with respect to the base, a cover plate attached to the base, and a driver configured to drive the base and the holding unit, wherein the driver is configured to, in a state in which the cover plate covers a surface of the substrate held by a substrate chuck, drive the holding unit between a first space on a side of a substrate chuck where interference with the substrate chuck does not occur and a second space between a chuck surface of the substrate chuck and the substrate raised from the chuck surface.

Further features of the present invention will become apparent from the following description of exemplary embodiments (with reference to the attached drawings).

### BRIEF DESCRIPTION OF THE DRAWINGS

FIG. 1 is a side view showing the configuration of an imprint apparatus;

FIG. 2 is a plan view showing the configuration of the imprint apparatus;

FIG. 3 is a flowchart showing the operation of the imprint apparatus;

FIGS. 4A to 4D are views showing the configuration of a substrate holding device;

FIGS. 5A and 5B are views showing a state in which a substrate process is executed using a top plate that transmits light;

FIGS. 6A to 6D are views showing a substrate transfer operation;

FIGS. 7A to 7D are views showing a substrate transfer operation;

FIG. 8 is a view for explaining an article manufacturing method; and

FIGS. 9A to 9D are views showing a substrate transfer operation.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following embodiments, the present invention will be described using, as an example, an imprint apparatus that forms a pattern on an imprint material on a substrate using a mold that is an original. However, the present invention is not limited to the imprint apparatus. For example, the present invention can also be applied to another lithography apparatus such as an exposure apparatus that transfers the pattern of an original to a substrate via a projection optical system.

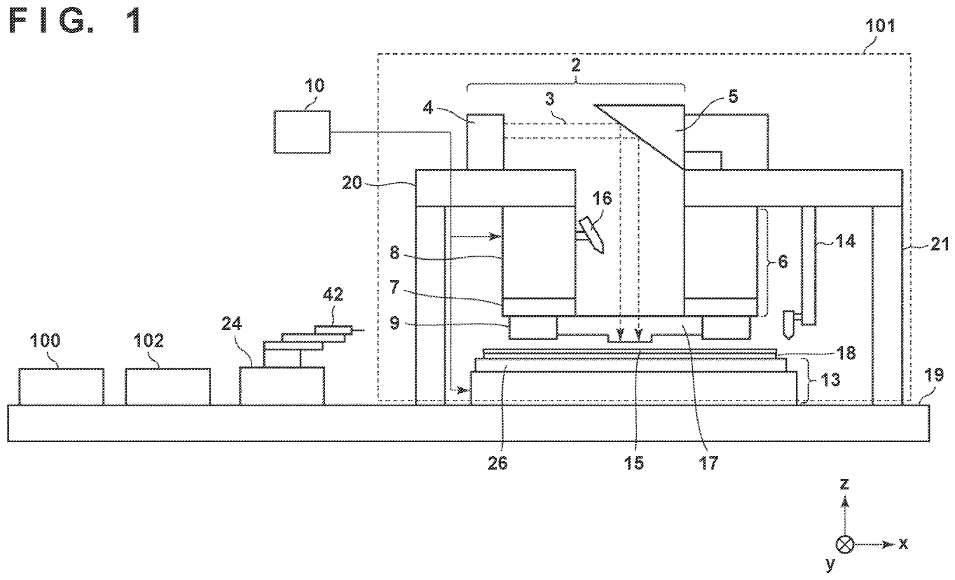

FIG. 1 is a schematic view (side view) of an imprint apparatus 1 according to the embodiment. In this specification and the accompanying drawings, directions are indicated on an xyz coordinate system in which a horizontal plane is defined as an xy plane. In general, a substrate is placed on a substrate stage such that its surface is parallel to the horizontal plane (xy plane). Hence, directions orthogonal to each other in a plane along the surface of the substrate will be defined as the x-axis and the y-axis hereinafter, and a direction perpendicular to the x-axis and the y-axis will be defined as the z-axis. Also, directions parallel to the x-axis, the y-axis, and the z-axis in the xyz coordinate system will be defined as the x direction, the y direction, and the z direction, respectively, hereinafter, and a rotation direction about the x-axis, a rotation direction about the y-axis, and a rotation direction about the z-axis will be defined as the θx direction, the θy direction, and the θz direction, respectively.

Firstly, an overview of an imprint apparatus according to an embodiment will be described. The imprint apparatus is an apparatus that brings an imprint material supplied onto a substrate into contact with a mold and supplies curing energy to the imprint material to form a pattern of the cured material to which a concave-convex pattern of the mold is transferred.

As an imprint material, a curable composition (to be sometimes called an uncured resin) that is cured upon application of curing energy is used. As curing energy, electromagnetic waves, heat, or the like can be used. Electromagnetic waves can be, for example, light selected from the wavelength range of 10 nm or more and 1 mm or less, for example, infrared light, visible light, or ultraviolet light, or the like. A curable composition can be a composition that is cured by being irradiated with light or by being heated. Of these compositions, a photo-curable composition that is cured by being irradiated with light contains at least a polymerizable compound and a photopolymerization initiator, and may further contain a non-polymerizable compound or a solvent, as needed. A non-polymerizable compound is at least one type of compound selected from the group consisting of a sensitizer, hydrogen donor, internal mold release agent, surfactant, antioxidant, and polymer component. An imprint material supply apparatus (corresponding to a supply unit 14 shown in FIG. 1) can arrange an imprint material on a substrate in the form of droplets or islands or films formed from a plurality of droplets connected to each other. The viscosity (the viscosity at 25° C.) of the imprint material can be, for example, 1 mPa·s or more and 100 mPa·s or less. As a material for a substrate, for example, glass, ceramic, metal, semiconductor, or resin can be used. The surface of a substrate may be provided with a member made of a material different from that of the substrate, as needed. For example, a silicon wafer, a compound semiconductor wafer, silica glass, or the like is used as the substrate.

Referring to FIG. 1, a transfer unit 101 performs an imprint process in which a contact step of bringing an imprint material 15 on a substrate 18 into contact with a mold 17 is performed, thereby forming a pattern of the imprint material. The imprint process can also include a supply step of supplying the imprint material 15 onto the surface of the substrate 18, and a curing step of curing the imprint material 15 after the contact step.

In this embodiment, as an imprint material curing method, the imprint apparatus 1 employs a photocuring method of curing the imprint material by irradiation of ultraviolet rays (UV light). Hence, the imprint apparatus 1 cures the imprint material 15 by irradiating it with ultraviolet rays in a state in which the imprint material 15 on the substrate 18 and the mold 17 are in contact, thereby forming the pattern of the imprint material on the substrate 18. However, the imprint apparatus 1 maycure the imprint material 15 by irradiation of light in another wavelength range, or may employ a method using another energy, for example, a heat-curing method of curing the imprint material 15 by heat.

Conventionally, a material with high volatility is used as the imprint material. Hence, a method of repeating supply of an imprint material and a contact step for each shot region is generally used. In recent years, an imprint material with low volatility has been developed. For this reason, a method of batch-applying the imprint material to the whole surface of a substrate in advance by spin coating or the like is also being adopted. According to the batch application of the imprint material, since the step of supplying the imprint material for each shot region can be omitted, productivity can be expected to improve. In this embodiment, a configuration using the latter batch application of an imprint material will mainly be described. Note that an effect of suppressing adhesion of a foreign substance can be obtained in both methods, as will be described later.

A method of repeating the contact step after the imprint material 15 is supplied at once onto the surface of the substrate 18 will be described below, but the present invention is not limited to this. For example, the imprint process may be executed by supplying the imprint material 15 onto the surface of the substrate 18 not at once but partially, and alternately repeating the supply of the imprint material 15 and the contact step. For both cases, in this embodiment, an effect of reducing adhesion of a foreign substance to the substrate 18 and an effect of suppressing volatilization of the imprint material 15 can be expected.

The imprint apparatus 1 can include a curing unit 2, an imprint head 6 that holds the mold 17, a substrate stage 13 that holds the substrate 18, a supply unit 14, an alignment measurement unit 16, and a control unit 10. The curing unit 2 irradiates the mold 17 with ultraviolet rays in the imprint process. The curing unit 2 includes, for example, a light source 4, and a plurality of optical systems 5 configured to adjust ultraviolet rays 3 irradiated from the light source 4 to appropriate light.

The mold 17 is a mold that has, for example, a rectangular outer peripheral portion, and has, on a surface facing the substrate 18, a pattern region in which an uneven pattern to be formed on the imprint material 15 supplied onto the substrate 18 is formed in a three-dimensional shape. Note that a material such as quartz that transmits ultraviolet rays is used as the material of the mold 17.

The imprint head 6 (forming portion) can include, for example, a mold chuck 7, a mold stage 8, and a mold shape correction mechanism 9. The mold chuck 7 holds the mold 17 by a mechanical holding means such as a vacuum suction force or an electrostatic attraction force. Also, the mold chuck 7 is held by the mold stage 8 by a mechanical holding means. The mold stage 8 includes a driving system configured to decide the interval between the mold 17 and the substrate 18 when bringing the mold 17 into contact with the substrate 18. The mold stage 8 moves the mold 17 in the z direction by the driving system. Note that the driving system of the mold stage 8 mayhave a function of moving the mold 17 not only in the z direction but also in, for example, the x direction, the y direction, the θx direction, the θy direction, and the θz direction. The mold shape correction mechanism 9 is a mechanism configured to correct the shape of the mold 17, and is installed at each of a plurality of points to surround the outer peripheral portion of the mold.

The substrate stage 13 holds the substrate 18, and corrects the translational shift of the mold 17 and the substrate 18 in the xy plane when bringing the mold 17 and the substrate 18 into contact. The substrate stage 13 includes a substrate holding device including a substrate chuck 26. The substrate chuck 26 sucks and holds the substrate 18. In an example, the method of sucking the substrate 18 can be a vacuum suction method. In place of the vacuum suction method, another chucking method such as an electrostatic attraction method may be used. The substrate stage 13 includes a driving system to be driven in the x direction and the y direction to correct the translational shift of the mold 17 and the substrate 18 in the xy plane. The driving system in the x direction and the y direction may be formed by a plurality of driving systems such as a coarse driving system and a fine driving system. Furthermore, a driving system for position adjustment in the z direction, a position adjustment function for the substrate 18 in the θz direction, and a tilt function for correcting a tilt of the substrate 18 maybe provided.

The substrate 18 can be a member made of glass, ceramic, a metal, a semiconductor, a resin, or the like. A layer of another material different from the member may be formed on the surface of the member, as needed. The substrate 18 is, for example, a silicon wafer, a compound semiconductor wafer, a silica glass plate, or the like. The transfer unit 101 repeats the imprint process for each of a plurality of shot regions, thereby forming a pattern on the substrate 18. Note that as the substrate 18, not only a substrate for forming a pattern but also a maintenance specific substrate used for foreign substance detection or the like may be used. The imprint apparatus 1 can further include a base surface plate 19 configured to hold the substrate stage 13, a bridge surface plate 20 configured to hold the imprint head 6, and a column 21 configured to support the bridge surface plate 20.

If the imprint material is not applied at once to the whole surface of the substrate but supplied for each shot region, the supply unit 14 (dispenser) can be arranged in the apparatus. The supply unit 14 includes, for example, a discharge nozzle (not shown), and the imprint material 15 is supplied from the discharge nozzle onto the substrate 18. Note that in this embodiment, a curable composition having such a characteristic that is cured by ultraviolet rays is used as the imprint material 15. The amount of the imprint material 15 to be supplied can be decided based on the necessary thickness of the imprint material or the density of the pattern to be formed.

The alignment measurement unit 16 is a measurement unit configured to detect alignment marks formed on the mold 17 and the substrate 18 and measure positional shifts in the x and y directions or shape difference between the pattern formed on the substrate and the pattern region of the mold.

A preprocessing unit 100 is a unit that executes a preprocess for the substrate before the substrate 18 is conveyed to the transfer unit 101. A post-processing unit 102 is a unit that executes a post-process of the substrate 18 after a pattern is formed on the substrate 18 by the transfer unit 101. A conveyance unit 24 conveys the substrate 18 by a hand 42 in the imprint apparatus 1.

The control unit 10 controls the operations of the units forming the imprint apparatus 1 and adjustment. The control unit 10 is formed by, for example, a computer, and connected to each unit of the imprint apparatus 1 via a line, and can control each unit in accordance with a program or the like.

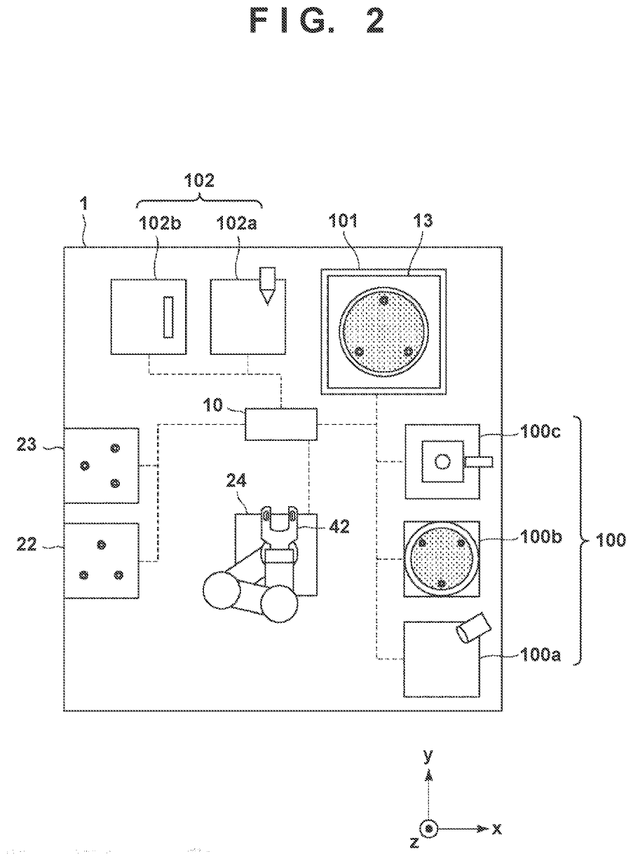

FIG. 2 is a plan view showing the configuration of the imprint apparatus 1. In this embodiment, the preprocessing unit 100 can include a foreign substance inspection unit 100a, a temperature adjustment unit 100b, and an alignment unit 100c. The post-processing unit 102 can include an exposure unit 102a and an overlay inspection unit 102b. Also, the imprint apparatus 1 can include an inline station configured to transfer the substrate 18 between the inside and the outside of the imprint apparatus 1. The inline station can include a loading station 22 and an unloading station 23. For example, if a device such as a coater developer or an Equipment Front End Module (EFEM) is connected to the imprint apparatus 1, first, the substrate 18 is conveyed to the loading station 22. After that, the substrate 18 undergoes a substrate process in each unit. The units and stations that perform the substrate process each include a substrate holding device including the substrate chuck 26. That is, the imprint apparatus according to this embodiment includes a plurality of substrate holding devices. The substrate 18 that has undergone the substrate process is conveyed to the unloading station 23. The loading station 22 and the unloading station 23 form one of the plurality of substrate holding devices in the imprint apparatus 1. In this embodiment, the loading station 22 and the unloading station 23 are handled as a common unit, and operated by adjusting the timing of loading/unloading.

The above-described components are not indispensable in the apparatus and change depending on the specifications and the standard of the transfer step. The components in the apparatus are not indispensable if the same measurement and the like as described above are executed by a measurement device and the like formed outside the transfer device.

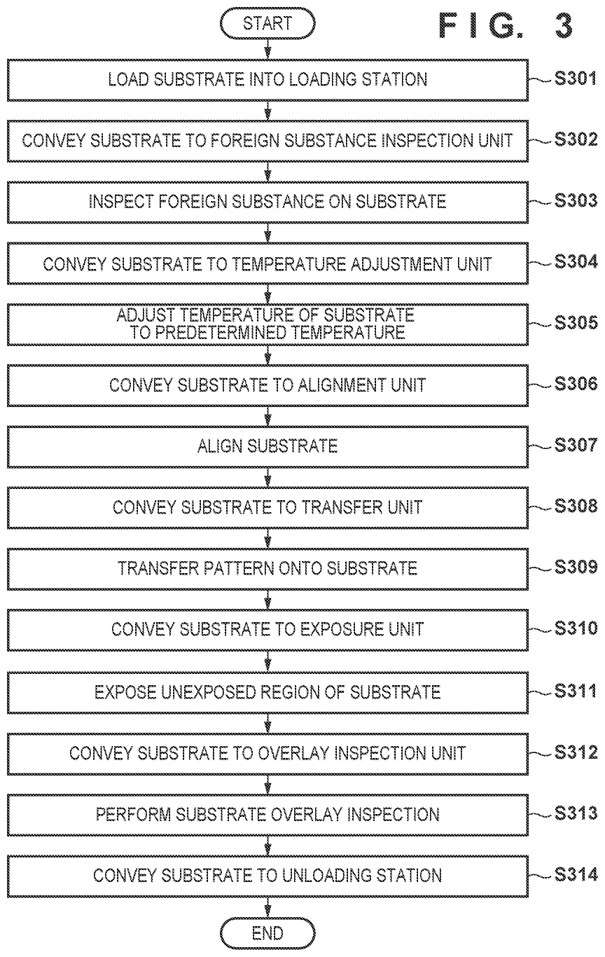

The operation of the imprint apparatus 1 from conveyance of the substrate 18 to the loading station 22 to conveyance to the unloading station 23 will be described with reference to FIG. 3. FIG. 3 is a flowchart showing the procedure of the substrate process performed in the imprint apparatus 1. The substrate process performed in the imprint apparatus 1 is executed by the control unit 10 controlling each unit of the imprint apparatus 1.

In step S301, the substrate 18 is loaded into the loading station 22 by a substrate conveyance device (not shown). Conveyance of the substrate 18 in the imprint apparatus 1 to be described below is performed by the conveyance unit 24. The conveyance unit 24 is one of the plurality of substrate holding devices in the imprint apparatus 1.

In step S302, the conveyance unit 24 conveys the substrate 18 to the foreign substance inspection unit 100a. In step S303, the foreign substance inspection unit 100a inspects a foreign substance on the substrate 18. As the foreign substance inspection method, for example, the evaluation surface of the substrate 18 is irradiated with light that obliquely enters the substrate 18. At this time, if the evaluation surface of the substrate 18 is flat, the light is regularly reflected. If some unevenness exists, the light is scattered. The foreign substance inspection unit 100a detects the scattered light, thereby determining whether an uneven structure exists, that is, a foreign substance adheres to the evaluation surface of the substrate 18. A method of detecting a foreign substance based on a difference from previous and succeeding shots, which is obtained by observing an image, may be employed. In this case, since a fine foreign substance is inspected, a scope having high resolving power needs to be mounted. The foreign substance inspection unit 100a is one of the plurality of substrate holding devices in the imprint apparatus 1.

In step S304, the conveyance unit 24 conveys the substrate 18 to the temperature adjustment unit 100b. In step S305, the temperature adjustment unit 100b adjusts the temperature of the substrate 18 such that the substrate 18 obtains a predetermined temperature. By the temperature change of the substrate 18, expansion/contraction of the substrate 18 occurs in accordance with the thermal expansion coefficient of the substrate material, and a temperature magnification error is generated. For this reason, if a high pattern accuracy is required, precise temperature management is necessary. Hence, the temperature adjustment unit 100b performs temperature leveling such that the substrate 18 obtains a predetermined temperature. In general, the temperature of the substrate 18 is adjusted using a temperature adjustment plate (a plate in which a heater or a refrigerant channel is formed) arranged in the substrate holding device of the temperature adjustment unit 100b. The temperature adjustment unit 100b is one of the plurality of substrate holding devices in the imprint apparatus 1.

In step S306, the conveyance unit 24 conveys the substrate 18 to the alignment unit 100c. In step S307, the alignment unit 100c adjusts at least one (prealignment state) of the position and the direction of the substrate 18 such that the substrate 18 is correctly conveyed to a target position on the substrate stage 13. Hence, the alignment unit 100c may be called a prealignment unit. For example, if the substrate is a silicon substrate, the alignment unit 100c can obtain the position and the direction of the substrate 18 by detecting an orientation flat indicating the crystal orientation of the substrate, a notch position, or a substrate outer shape. If the substrate has a pattern, the position and the direction of the substrate 18 can be obtained based on the detected pattern.

Along with improvement of the required alignment accuracy, more detailed measurement needs to be performed. Although various kinds of measurement of the substrate 18 can be performed in the transfer unit 101, lowering of the productivity of the substrate process pose a problem in that case. Hence, the lowering of the productivity of the substrate process can be suppressed by forming the alignment unit 100c that is separated from the transfer unit 101 and specialized to measurement. In this embodiment, a configuration in which the function of performing various kinds of measurement is added to the above-described alignment unit 100c will be described. However, another measurement unit may further be formed. The alignment unit 100c may for example, optically measure various kinds of marks or patterns formed on the substrate 18 and perform calculation together with a stage driving amount, thereby calculating a shot array or a shot shape in advance. This makes it possible to acquire data necessary for improvement of the alignment accuracy without lowering the productivity. In some cases, a mark or pattern on the substrate, which is formed in a preceding step, cannot be used due to the influence of a foreign substance, or the measurement result includes an error due to distortion or unevenness. Hence, the alignment unit 100c can observe the mark or pattern scheduled to be used in the transfer unit 101 in advance and confirm whether it is usable for measurement.

In step S308, the conveyance unit 24 conveys the substrate 18 to the substrate stage 13 in the transfer unit 101. In step S309, the transfer unit 101 performs the imprint process of bringing the mold 17 into contact with the imprint material 15 on the substrate 18 and curing the imprint material 15, thereby transferring the uneven pattern of the mold 17 onto the substrate 18. In the imprint process, relative alignment between the substrate 18 and the mold 17 is also executed. Here, relative alignment by a die-by-die alignment method can be performed. In the die-by-die alignment method, in the contact step, a relative position is calculated by observing a mark on the mold 17 and a mark on the substrate 18, and relative alignment is performed based on the result. Also, as correction of the shot shape, the shape of the mold 17 maybe changed by applying a pressure to the side surface of the mold 17, or the substrate 18 may locally be irradiated with light to generate temperature unevenness, and the substrate may be corrected into a desired shot shape by the expansion difference of the substrate caused by input heat. As original data for the shot shape correction, measurement on the transfer unit 101, measurement in step S307 described above, pre-measurement outside the apparatus, or a past transfer result may be used. The substrate stage 13 that holds the substrate 18 in the transfer unit 101 is one of the plurality of substrate holding devices in the imprint apparatus 1.

In step S310, the conveyance unit 24 conveys the substrate 18 to the exposure unit 102a. In step S311, the exposure unit 102a cures, by light irradiation, the imprint material in a region where the imprint process is not executed by the transfer unit 101. Usually, the silicon substrate processed by the imprint apparatus is a circular substrate, and the shape of a shot region is rectangular. In this case, since the rectangular shot region cannot be ensured near the outer periphery of the circular substrate, the imprint process may not be performed. In addition, a non-imprint region may occur in a shot region. However, if the imprint material in the non-imprint region volatilizes in a step after the imprint process, a structural difference is generated between an imprinted region and the non-imprint region. In the non-imprint region, the imprint material volatilizes, and protection by the imprint material is lost. For this reason, for example, in an etching step, a portion without the imprint material or a periphery thereof may largely be etched. This may affect an article to be produced. Hence, the exposure unit 102a executes a process of irradiating the non-imprint region with ultraviolet light to cure the imprint material, like the imprinted region. The exposure unit 102a is one of the plurality of substrate holding devices in the imprint apparatus 1. Exposure light from the exposure unit 102a may be light guided from the light source 4 of the transfer unit 101 or may be light from a small light source sch as an LED or an LD. In recent years, for example, since LEDs are developed with various kinds of wavelengths from ultraviolet rays to the infrared region, an appropriate LED is selected in accordance with the imprint material.

In step S312, the conveyance unit 24 conveys the substrate 18 to the overlay inspection unit 102b. In step S313, the overlay inspection unit 102b inspects the overlay accuracy of the pattern transferred by the transfer unit 101. Since the inspection is performed in the imprint apparatus 1, feedback can be done immediately as compared to a method of performing inspection outside the apparatus. The inspection can include measuring, at a plurality of points, the relative position between a mark formed on the substrate 18 in advance and a mark formed by transfer by the transfer unit 101 in step S309, and obtaining distortion or position deviation of the transfer pattern based on the measurement result. The overlay inspection unit 102b is one of the plurality of substrate holding devices in the imprint apparatus 1. If the imprint apparatus 1 includes a scope having high resolving power, it may be possible to observe the transfer pattern and observe whether any failure is in the transfer step. For example, in a case of transfer in imprint, it is possible to observe whether a pattern is formed or not and whether an unfilled part exists or not, and a resist thickness or the like can also be observed based on filling property between shots, the shades of image, and the difference in tint.

In step S314, the conveyance unit 24 conveys the substrate 18 to the unloading station 23. After that, the substrate 18 is conveyed from the unloading station 23 to the outside of the imprint apparatus 1 by a substrate conveyance device (not shown).

Here, an influence that may occur due to a foreign substance adhered to the substrate 18 or volatilization of the imprint material will be described. If a foreign substance adheres to the substrate 18 during the time from loading of the substrate 18 into the loading station 22 to conveyance to the transfer unit 101, the foreign substance is sandwiched between the substrate 18 and the mold 17 in the imprint process. If the foreign substance is sandwiched between the substrate 18 and the mold 17, a defect occurs in the transfer pattern, and additionally, the pattern of the mold 17 is broken, and the mold 17 cannot be used in the subsequent imprint process. Even in a case where a foreign substance adheres after the imprint process, the foreign substance causes a process failure in the subsequent steps. For this reason, foreign substance adhesion needs to be avoided.

### (Configuration of Substrate Holding Device)

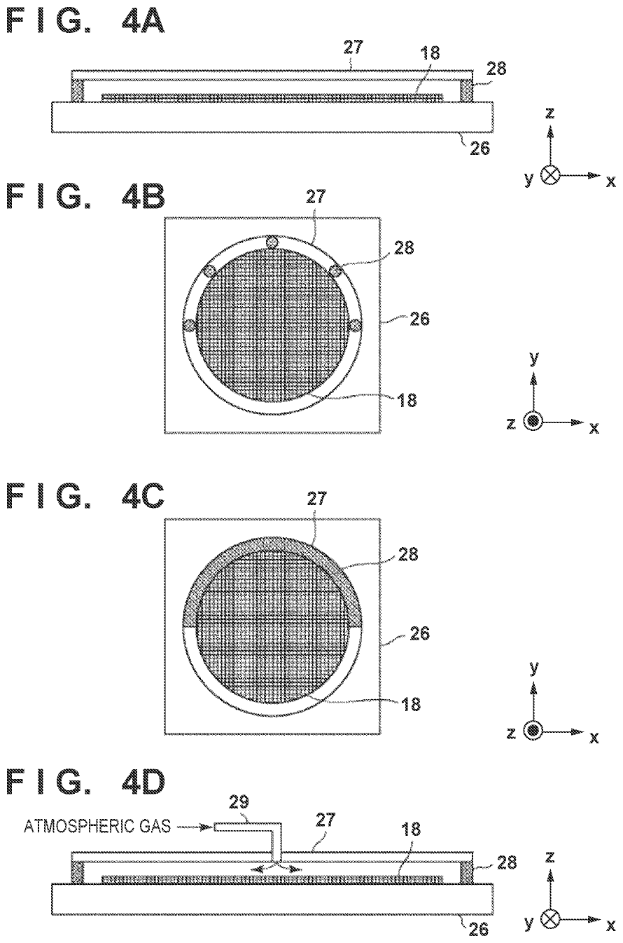

As described above, each unit of the imprint apparatus 1 includes a substrate holding device including the substrate chuck 26. The configuration of these substrate holding devices will be described below. First, an example of the configuration of the substrate holding device including a top plate that is a cover plate will be described with reference to FIGS. 4A to 6D.

FIGS. 4A and 4D are side views of the substrate holding device, and FIGS. 4B and 4C are top views of the substrate holding device. The substrate holding device includes the substrate chuck 26, a top plate 27, and a member 28. The substrate 18 is mounted on the substrate chuck 26, and the substrate chuck 26 holds the bottom surface of the substrate 18 by vacuum chucking or electrostatic chucking. The top plate 27 is located on the upper surface side of the substrate 18 held by the substrate chuck 26, and plays a role of protecting the substrate 18. Protection of the substrate 18 includes preventing a foreign substance from adhering to the substrate 18 and suppressing volatilization of the imprint material applied to the substrate 18. If highly precise driving is necessary, the substrate holding device may include a linear motor, an interferometer for position measurement, or an encoder.

The member 28 is arranged on the substrate chuck 26 and holds the top plate 27. The member 28 need not cover the space between the substrate chuck 26 and the top plate 27 to form a closed space and need only be able to hold the top plate 27. The top plate 27 is formed close to the substrate 18, and can therefore protect it from a foreign substance from above, and at the same time, suppress flow-in of a foreign substance from a side surface. For example, a plurality of columnar members 28 maybe arranged, as shown in FIG. 4B, or one member 28 maybe arranged, as shown in FIG. 4C such that a space capable of transferring the substrate 18 is formed in the direction of a side surface of the substrate 18.

In general, on a boundary surface between a fluid and a solid, the fluid generates viscosity in accordance with the distance to the boundary surface. This exerts influence in a very narrow region near the boundary surface, and as the distance from the boundary surface increases, the influence of viscosity is substantially eliminated. A substrate holding device according to this comparative example forms a space where fluid viscosity is generated between the substrate 18 and the top plate 27 by arranging these close to each other.

As a constant laminar flow solution of a fluid having viscosity flowing through a circular pipe, there is the equation of Hagen-Poiseuille flow. An equation that is obtained by deforming this equation and represents the flow velocity of a fluid sandwiched between two stationary parallel flat plates is the equation of plane Poiseuille flow. The equation of plane Poiseuille flow is an equation representing that the flow velocity is low at a position close to the flat plates but becomes high at a position far from the flat plates. In other words, if the interval between the two parallel flat plates is decreased, the flow velocity of the fluid between the flat plates decreases, and the fluid flowing between the flat plates is difficult to move. Even in this embodiment, if the interval between the upper surface of the substrate 18 and the lower surface of the top plate 27 is set to, for example, 2 mm or less, an effect of reducing flow-in of a gas from the side surface can be expected, and adhesion of a foreign substance to the substrate 18 can be suppressed. Also, according to the equation of plane Poiseuille flow, if the interval between the upper surface of the substrate 18 and the lower surface of the top plate 27 is made narrower, the above-described effect can be improved. Note that since the characteristic of viscosity changes depending on the type of the gas, it is preferable to appropriately set the optimum interval between the upper surface of the substrate 18 and the lower surface of the top plate 27.

Also, as shown in FIG. 4D, when an atmospheric gas is injected from a vent hole 29 provided in the top plate 27 to set the space between the top plate 27 and the substrate 18 to a positive pressure with respect to the outside air, the effect of suppressing flow-in of a foreign substance from the side surface can be improved.

Even the volatilization of the imprint material can be suppressed by arranging the substrate 18 and the top plate 27 close to each other. When the interval between the substrate 18 and the top plate 27 is made narrow, the gas is difficult to flow in and flow out. For this reason, it is possible to maintain the saturated steam amount of the imprint material in this space and suppress volatilization of the imprint material. Note that since the characteristic changes depending on the type of the imprint material, it is preferable to appropriately set the optimum interval between the upper surface of the substrate 18 and the lower surface of the top plate 27. In a case where an atmospheric gas is injected, as shown in FIG. 4D, volatilization of the imprint material can be expected to be suppressed by using an atmospheric gas containing the saturated steam of the imprint material.

### (Material of Top Plate)

A preferable material used for the top plate 27 will be described. Most of the units that perform the substrate processes for the substrate 18 in the imprint apparatus 1 perform the process in a noncontact state to the upper surface of the substrate 18. Hence, if the top plate 27 formed on the upper surface side of the substrate 18 is made of a material (for example, quartz) that transmits light used in the foreign substance inspection unit 100a or light used in exposure by the exposure unit 102a, it is possible to execute the substrate processes while forming the top plate 27 in the substrate holding device. This can protect the upper surface of the substrate 18 even in the substrate processes.

More specifically, in the foreign substance inspection unit 100a, the temperature adjustment unit 100b, the alignment unit 100c, the exposure unit 102a, and the overlay inspection unit 102b other than the transfer unit 101 described above, the substrate processes can be executed while keeping the top plate 27 arranged. Also, substrate processes executable in a noncontact state to the upper surface of the substrate, such as various kinds of measurement using light, can be performed while keeping the top plate 27 arranged. In the transfer unit 101, however, since the mold 17 needs to be brought into contact with the upper surface of the substrate 18 in the imprint process, the substrate processes cannot be performed while keeping the top plate 27 formed.

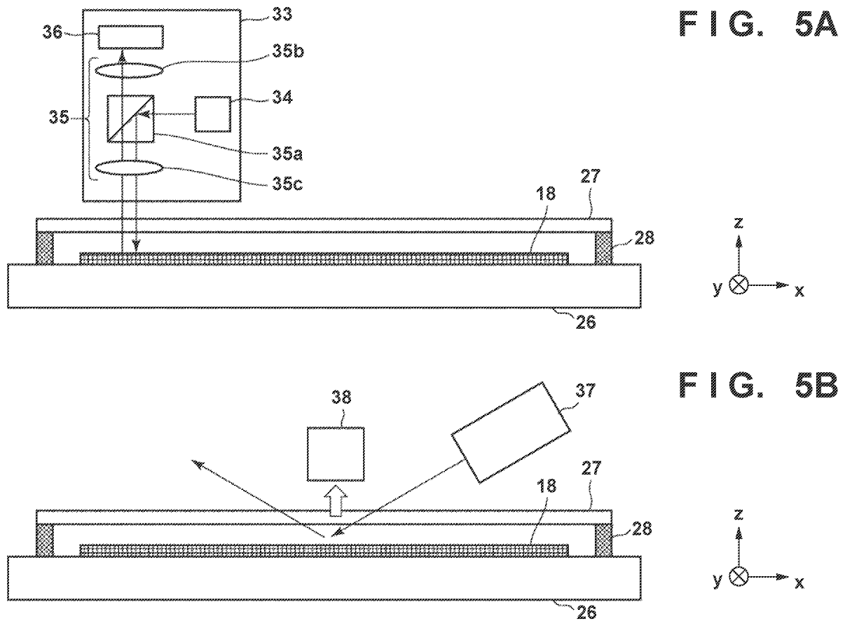

An example in which a substrate process is executed in a noncontact state of the substrate 18 while keeping the top plate 27 formed in the substrate holding device will be described with reference to FIGS. 5A and 5B. FIG. 5A is a view showing an example in which the upper surface of the substrate 18 is optically measured by a measurement unit 33. FIG. 5A corresponds to a substrate process of performing observation of the substrate upper surface by the above-described alignment unit 100c or overlay inspection unit 102b or foreign substance inspection using an image.

The measurement unit 33 includes a light source 34, an optical member 35, and a sensor 36. The optical member 35 is formed by a half mirror 35a, a lens 35b, and a lens 35c. Illumination light emitted by the light source 34 passes via the optical member 35, passes through the top plate 27, and irradiates a desired position on the substrate 18. After that, the light returned from the substrate 18 passes through the top plate 27, passes via the optical member 35, and enters the sensor 36.

As the light source 34, an LED that has become smaller in recent years may be used. Also, as for the light source 34, light may be guided, via an optical fiber or the like, from a light source such as a separately formed mercury lamp. The type of the sensor 36 is preferably selected in accordance with the application purpose. A signal from the substrate 18 is acquired using an image sensor or a line sensor, and a position is calculated based on the feature of the signal waveform.

FIG. 5B is a view showing an example in which foreign substance inspection is performed by the above-described foreign substance inspection unit 100a. A light source 37 irradiates a desired position on the substrate 18 with light by oblique incidence. If a foreign substance exists at the illuminated position, scattered light is generated. Hence, a sensor 38 receives the scattered light, thereby detecting a foreign substance.

Hence, if the top plate 27 is made of a material that transmits light, it is possible to execute the substrate process in each unit while keeping the top plate 27 formed in the substrate holding device and suppress adhesion of a foreign substance to the substrate 18 or volatilization of the imprint material in the substrate process.

In addition, an electrostatic force may be applied to the top plate 27 or the member 28 to attract a foreign substance and prevent the foreign substance from adhering to the substrate 18.

### (Substrate Transfer Method)

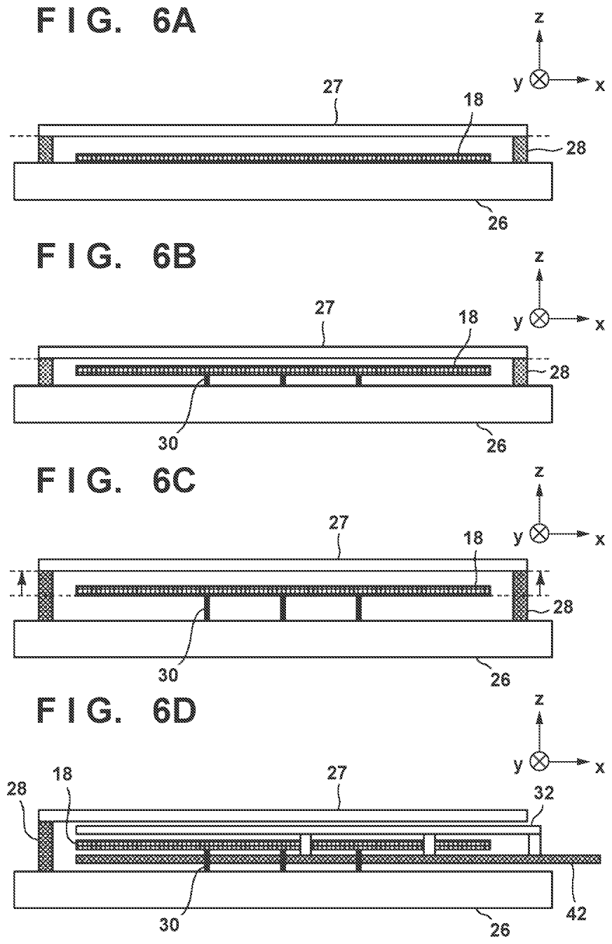

When the substrate 18 is conveyed from a unit to the substrate holding device of another unit of the destination, the substrate is held by the hand 42 and conveyed. A substrate transfer method of transferring the substrate from the substrate holding device to the hand 42 (first comparative example) will be described with reference to FIGS. 6A to 6D. FIGS. 6A to 6D are views showing the operation of the substrate holding device when transferring the substrate 18. From a state in which the substrate 18 is placed on the substrate chuck 26 of the substrate holding device, as shown in FIG. 6A, the substrate 18 is raised by projecting portions 30 projecting from the substrate chuck 26 so as not to hit the top plate 27, as shown in FIG. 6B. The hand 42 is inserted into the space formed by raising the substrate 18 to receive the substrate 18.

If the interval between the substrate chuck 26 and the top plate 27 is narrow, it may be impossible to sufficiently raise the substrate 18 by the projecting portions 30 and insert the hand 42. In this case, as shown in FIG. 6C, the members 28 holding the top plate 27 are expanded/contracted to ensure the space under the substrate 18 to insert the hand 42. At this time, the interval between the top plate 27 and the substrate 18 is preferably held such that no foreign substance adheres to the upper surface of the substrate 18. That is, the top plate 27 and the substrate 18 are preferably simultaneously raised. However, the present invention is not limited to this, and these need not always be raised simultaneously.

A cover plate 32 having the same function as the top plate 27 maybe arranged on the hand 42 that receives the substrate 18. As shown in FIG. 6D, the substrate is transferred in a state in which the top plate 27, the cover plate 32, the substrate 18, the hand 42, and the substrate chuck 26 are inserted alternately from the upper side. If the substrate 18 is thus transferred, the substrate 18 can be protected by the cover plate 32 even after the substrate 18 is transferred to the hand 42.

Note that this configuration is merely an example, and, for example, even if the position of the top plate 27 and the of the cover plate 32 at the time of transfer may be exchanged, the same effect can be obtained.

Also, when the substrate holding device receives the substrate 18 from the hand 42, a procedure reverse to the above-described procedure is executed, thereby transferring the substrate 18 while keeping it protected.

In the above-described first comparative example, a substrate transfer method in a case where the top plate is formed in each of the substrate holding device and the substrate conveyance device has been described. In the second comparative example to be described next, a substrate transfer method in which a substrate holding device simultaneously transfers the substrate and the top plate to a substrate holding device in which the top plate (cover) is not formed will be described.

In the second comparative example, the substrate 18 is mounted on the substrate chuck 26 on which the top plate 27 is formed, and these are conveyed as a group. At this time, if vacuum suction is used as the chucking of the substrate, a small power supply and a suction device may be mounted on the chuck to continue suction, or the suction force may be maintained by closing a suction valve. In electrostatic attraction, a small power supply and a static electricity generator may be mounted to continue suction, or suction of the substrate may be continued by blocking input/output of static electricity after suction. In other suction methods as well, it is possible to provide a component for continuing suction on the substrate chuck and convey the substrate that is kept sucked.

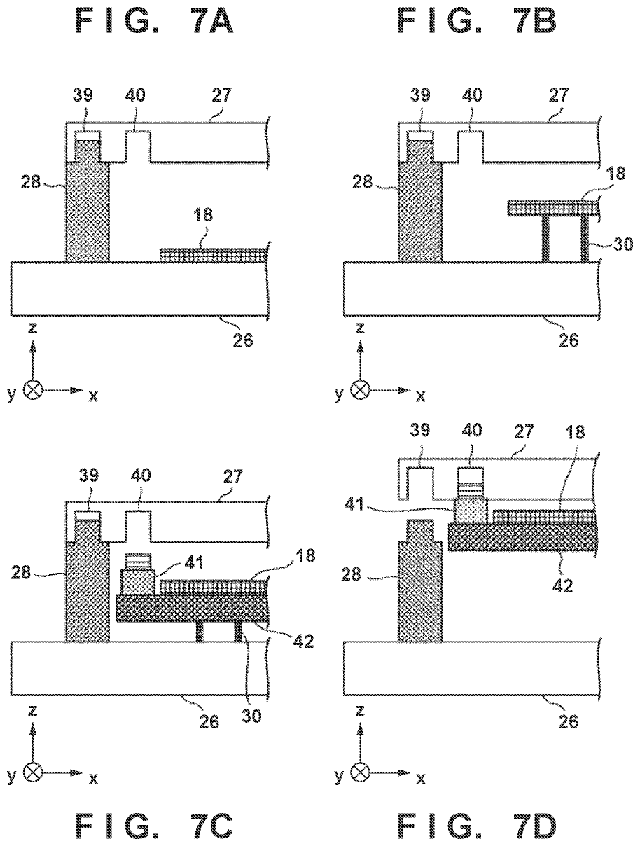

When conveying the substrate 18 to the substrate holding device of another unit, the substrate 18 is held by the hand 42 and conveyed. A substrate transfer method of transferring the substrate from the substrate holding device to the hand 42 (second comparative example) will be described with reference to FIGS. 7A to 7D. FIGS. 7A to 7D are views showing the operation of the substrate holding device when transferring the substrate 18 according to the second comparative example. The top plate 27 of the substrate holding device according to the second comparative example is provided with recesses 39 and 40, as shown in FIG. 7A, and the top plate 27 is held by inserting the member 28 to the recess 39.

From a state in which the substrate 18 is placed on the substrate chuck 26 of the substrate holding device, as shown in FIG. 7A, the substrate 18 is raised by the projecting portions 30 projecting from the substrate chuck 26 so as not to hit the top plate 27, as shown in FIG. 7B. Next, as shown in FIG. 7C, the hand 42 is inserted into the space formed by raising the substrate 18 to receive the substrate 18. At this time, the members 28 maybe expanded, like the first comparative example.

Next, the hand 42 is raised to the position where the top plate 27 exists, thereby simultaneously transferring the substrate 18 and the top plate 27 to the hand 42, and conveying these to another unit that is the destination. At this time, as shown in FIG. 7D, a member 41 formed on the hand 42 is inserted into the recess 40 of the top plate 27. When the member 41 is inserted into the recess 40, the top plate 27 is held by the hand 42. Also, as shown in FIG. 7D, the member 28 is only inserted into the recess of the top plate 27 and therefore detached from the recess 39.

If the substrate 18 is thus transferred, the substrate 18 can be protected by the top plate 27 even after the substrate 18 is transferred to the hand 42. Also, when the substrate holding device receives the substrate 18 from the hand 42, a procedure reverse to the above-described procedure is executed, thereby transferring the substrate and the top plate 27 while keeping the substrate 18 protected.

Also, the size of the top plate 27 is preferably substantially equal to or larger than the size of the substrate 18.

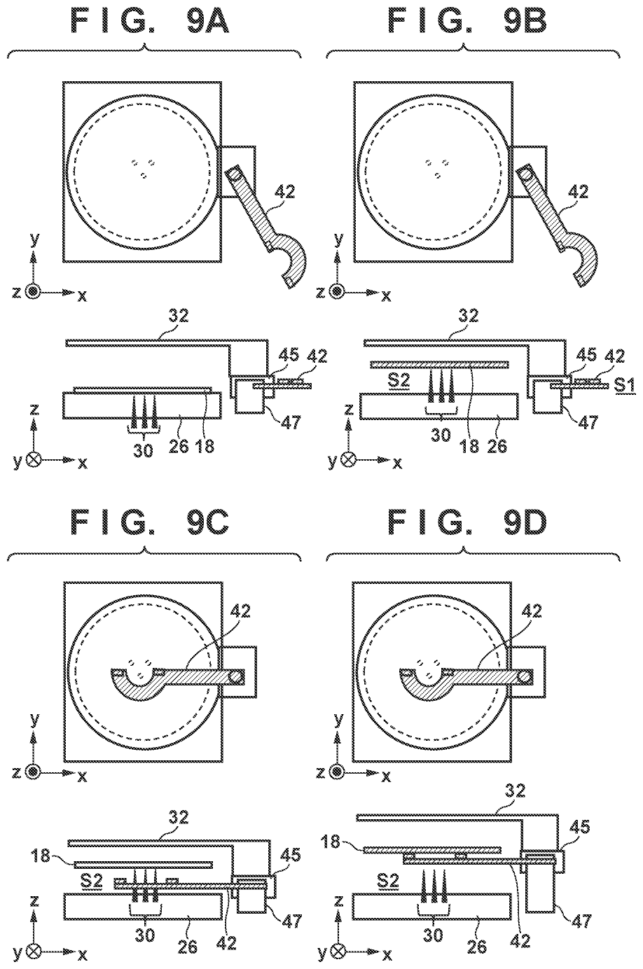

The configuration and the conveyance method of the conveyance apparatus according to the embodiment will be described below with reference to FIGS. 9A to 9D. In this embodiment, the hand 42 that is a holding unit can move between a first space S1 on a side of the substrate chuck 26 where interference with the substrate chuck 26 does not occur and a second space S2 (see FIG. 9B) between the chuck surface of the substrate chuck 26 and the substrate 18 raised from the chuck surface. In a state in which the cover plate 32 covers the surface of the substrate 18 held by the substrate chuck 26, a driver 47 to be described later is configured to drive the hand 42 between the first space S1 and the second space S2. In the first comparative example and the second comparative example, the cover plate and the hand move integrally. In this embodiment, however, the hand 42 moves in a state in which the cover plate 32 covers the surface of the substrate 18.

In the embodiment, the conveyance unit 24 is a conveyance apparatus that collects a substrate from the substrate stage of a unit and supplies the substrate to the substrate stage of another unit that is the destination. In FIG. 9A, the conveyance unit 24 includes a movable base 45. The cover plate 32 is attached to the upper portion of the base 45. The hand 42 is a holding unit that is attached to the base, holds the substrate 18, and is movable with respect to the base 45. In an example, the hand 42 is attached to turn in the θz direction with respect to the base 45. Also, the conveyance unit 24 includes the driver 47 that performs movement (rise and fall) in the z direction of the base 45 and turning drive of the substrate chuck 26 with respect to the base 45. The driver 47 can be controlled by the control unit 10.

Here, for substrate conveyance, the chuck of the substrate 18 by the substrate chuck 26 is canceled, and the substrate 18 is driven to rise from the chuck surface of the substrate chuck 26. For example, the plurality of pins 30 that project/retreat with respect to the chuck surface are arranged in the substrate chuck 26. If the plurality of pins 30 project from the chuck surface, the substrate 18 is supported and raised by the plurality of pins 30. Note that as the component that raises the substrate 18 from the chuck surface, an air pad or the like may be used in place of the plurality of pins 30.

As shown in FIG. 9A, the driver 47 drives the base 45 to a position where the cover plate 32 covers the surface of the substrate 18 held by the substrate chuck 26 while keeping the hand 42 located in the first space S1. The cover plate 32 preferably has an area equal to or larger than the area of the surface of the substrate 18. Also, the interval between the lower surface of the cover plate 32 and the surface of the substrate 18 in a state in which the cover plate 32 covers the surface of the substrate 18 is preferably 2 mm or less. This makes it possible to reduce flow-in of a gas from a side of the first space S1 and suppress adhesion of a foreign substance to the substrate 18.

After that, the control unit 10 cancels the chuck of the substrate 18 by the substrate chuck 26 and raises the plurality of pins 30, as shown in FIG. 9B. Thus, the substrate 18 rises from the chuck surface of the substrate chuck 26, and the second space S2 between the substrate 18 and the chuck surface of the substrate chuck 26 is formed.

As described above, in a state in which the cover plate 32 covers the surface of the substrate 18, the driver 47 receives a control instruction from the control unit 10 and makes the hand 42 enter the second space, as shown in FIG. 9C. Note that here, the driver 47 is configured to turn the hand 42 with respect to the base 45, but this is merely an example. The driver 47 maybe configured to, for example, linearly move the hand 42. The hand 42 has a shape that does not interfere with the plurality of pins 30.

Next, as shown in FIG. 9D, the driver 47 drives the base 45 upward such that the hand 42 comes into contact with the lower surface of the substrate 18. When the base 45 is driven upward, the hand 42 and the cover plate 32 integrally move upward. When the hand 42 comes into contact with the lower surface of the substrate 18, the hand 42 holds the substrate 18. In a state in which the hand 42 holds the substrate 18, and in a state in which the cover plate 32 covers the surface of the substrate 18, the driver 47 drives the base 45 to convey the substrate 18 to the destination based on a control instruction from the control unit 10. During the drive of the base 45, the hand 42 and the cover plate 32 integrally move.

By this operation, the substrate 18 is transferred. Thus, even after the substrate 18 is transferred to the hand 42, the substrate 18 can be protected by the cover plate 32. Also, when the substrate holding device of the unit of the moving destination receives the substrate 18 from the hand 42, a procedure reverse to the above-described procedure is executed, thereby transferring the substrate 18 while keeping it protected by the cover plate 32. Note that in the example shown in FIGS. 9A to 9D, the hand 42 and the cover plate 32 are integrated. The cover plate 32 maybe formed on one arm of a double arm type device, and the hand 42 maybe formed on the other arm.

In the above-described way, in a state in which the cover plate 32 is placed close to the substrate 18, the substrate 18 can be conveyed by the hand 42. This can effectively suppress adhesion of a foreign substance. Furthermore, volatilization of the imprint material applied to the substrate 18 can be suppressed.

Note that in this embodiment, a circuit pattern transfer mold formed by providing an uneven pattern on the mold 17 has been described. However, a mold (blank template) having a flat surface portion without an uneven pattern on the mold 17 maybe used. The blank template is used by a planarization apparatus that molds to planarize a composition on a substrate by the flat surface portion. That is, this embodiment can be applied to a molding apparatus (for example, an imprint apparatus or a planarization apparatus) that molds a composition on a substrate using a mold.

In the embodiment, an operation in an imprint apparatus has been described. However, the present invention is not limited to this. According to this embodiment, a top plate is formed at the time of holding a substrate, thereby preventing adhesion of a foreign substance to the substrate or volatilization of an applied material. For this reason, the configuration according to this embodiment can also be applied to, for example, an apparatus or unit used in a step of inspecting a defect on a substrate or overlay or a step of applying a material.

### <Embodiment of Method of Manufacturing Article>

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as at least some of the constituent members of the above-described articles or used temporarily as a resist mask. After etching or ion implantation is performed in the substrate processing step, the resist mask is removed.

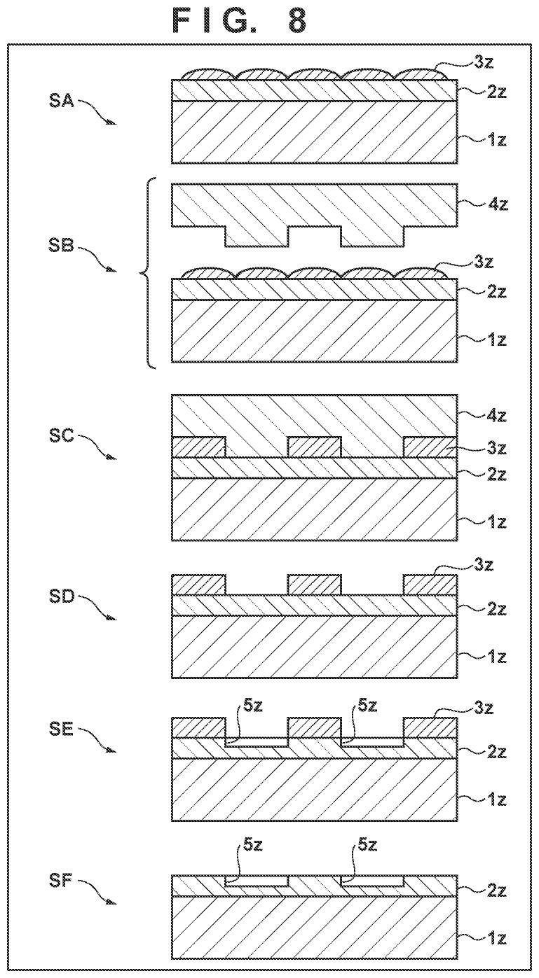

A method of manufacturing an article will be described next. As shown step SA of FIG. 8, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in step SB of FIG. 8, a side of a mold 4z for imprint with an uneven pattern is directed toward and made to face the imprint material 3z on the substrate. As shown in step SC of FIG. 8, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with energy for curing via the mold 4z, the imprint material 3z is cured.

As shown in step SD of FIG. 8, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the uneven pattern of the mold 4z is transferred to the imprint material 3z.

As shown in step SE of FIG. 8, when etching is performed using the pattern of the cured product as an etching resistant mask, a portion of the surface of the processed material 2z where the cured product does not exist or remains thin is removed to form a groove 5z. As shown in step SF of FIG. 8, when the pattern of the cured product is removed, an article with the grooves 5z formed in the surface of the processed material 2z can be obtained. Here, the pattern of the cured product is removed. However, instead of processing or removing the pattern of the cured product, it may be used as, for example, an interlayer dielectric film included in a semiconductor element or the like, that is, a constituent member of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-005314, filed Jan. 17, 2023 which is hereby incorporated by reference herein in its entirety.

What is claimed is:

1. A conveyance apparatus for conveying a substrate, comprising:
a movable base;
a holding unit attached to the base and configured to hold the substrate and be movable with respect to the base;
a cover plate attached to the base; and
a driver configured to drive the base and the holding unit,
wherein the driver is configured to, in a state in which the cover plate covers a surface of the substrate held by a substrate chuck, drive the holding unit between a first space on a side of a substrate chuck where interference with the substrate chuck does not occur and a second space between a chuck surface of the substrate chuck and the substrate raised from the chuck surface.

2. The apparatus according to claim 1, wherein
the driver
drives the base to a position where the cover plate covers the surface of the substrate held by the substrate chuck while keeping the holding unit located in the first space, and
drives the holding unit to the second space in the state in which the cover plate covers the surface of the substrate.

3. The apparatus according to claim 2, wherein after moving the holding unit to the second space, the driver drives the base upward such that the holding unit comes into contact with a lower surface of the substrate, and then, in a state in which the holding unit holds the substrate and in the state in which the cover plate covers the surface of the substrate, drives the base to convey the substrate to a destination.

4. The apparatus according to claim 1, wherein between the first space and the second space, the driver turns the holding unit with respect to the base.

5. The apparatus according to claim 1, wherein an interval between a lower surface of the cover plate and the surface of the substrate in the state in which the cover plate covers the surface of the substrate is not more than 2 mm.

6. The apparatus according to claim 1, wherein the cover plate has an area not less than area of the surface of the substrate.

7. A conveyance method for conveying a substrate, comprising:
while keeping a holding unit attached to a movable base of a conveyance apparatus and configured to be movable with respect to the base located in a first space on a side of a substrate chuck where interference with the substrate chuck does not occur, driving the base to a position where a cover plate attached to the base covers a surface of a substrate held by the substrate chuck;
raising the substrate from a chuck surface of the substrate chuck in a state in which the cover plate covers the surface of the substrate;
driving the holding unit to a second space between the substrate and the chuck surface in the state in which the cover plate covers the surface of the substrate;
to cause the holding unit to hold the substrate, driving the holding unit moved to the second space upward such that the holding unit comes into contact with a lower surface of the substrate; and
in a state in which the holding unit holds the substrate and in the state in which the cover plate covers the surface of the substrate, driving the base to convey the substrate to a destination.

8. A lithography apparatus comprising:
a substrate stage configured to hold a substrate;
a forming unit configured to form a pattern on the substrate held by the substrate stage; and
a conveyance apparatus defined in claim 1, which is configured to perform supply of the substrate to the substrate stage and collection of the substrate from the substrate stage.

9. An article manufacturing method comprising:
forming a pattern on a substrate using a lithography apparatus defined in claim 8; and
processing the substrate with the pattern formed thereon,
wherein an article is manufactured from the processed substrate.
